(19) United States
(12) Patent Application Publication
(10) Pub. No.: US 2022/0122860 A1
(43) Pub. Date: Apr. 21, 2022

(54) POWDER SPRAYING DEVICE FOR A SEMICONDUCTOR MOLDING PROCESS AND SPRAYING METHOD THEREOF

(71) Applicant: Powertech Technology Inc., Hukou Township (TW)

(72) Inventors: Po-Hung WU, Hukou Township (TW); Zun-Huan HUANG, Hukou Township (TW)

(73) Assignee: Powertech Technology Inc., Hukou Township (TW)

(21) Appl. No.: 17/216,209

(22) Filed: Mar. 29, 2021

(30) Foreign Application Priority Data
Oct. 21, 2020 (TW) 109136566

(51) Int. Cl. H01L 21/67; B29C 43/58; B29C 43/34; H01L 21/56

(52) U.S. Cl. CPC H01L 21/67126; B29C 43/58; B29C 2043/3455; H01L 21/565; B29C 43/34

(57) ABSTRACT

A powder spraying device has a first powder spraying tube and a second powder spraying tube arranged parallelly. The first powder spraying tube has a first opening formed on a bottom thereof. A first gate is mounted moveably on the first opening to selectively cover the first opening. The second powder spraying tube has a second opening formed on a bottom thereof. A second gate is mounted moveably on the second opening to selectively cover the second opening. When the first powder spraying tube and the second powder spraying tube are filled with different plastic particles, the first opening and the second opening are opened and closed at different times to spray different plastic particles so that the specific molding method requirements are met.

### CROSS-REFERENCE TO RELATED APPLICATIONS

This application is based upon and claims priority under 35 U.S.C. 119 from Taiwan Patent Application No. 109136566 filed on Oct. 21, 2020, which is hereby specifically incorporated herein by this reference thereto.

### BACKGROUND OF THE INVENTION

### 1. Field of the Invention

The present invention is related to a semiconductor molding process, and more particularly to a powder spraying device for a semiconductor molding process and a spraying method thereof.

### 2. Description of the Prior Arts

Semiconductor packages are commonly made of plastic, ceramics, glass, and metal for protecting the chip, buffering the stress, increasing heat dissipation and modularization. Among these materials, the plastic has the advantages of lower price, manufacturing easily, and more suitable for automated production comparing with other materials. Molding methods for plastic include two types, i.e. transfer molding and compression molding. One of the plastic, i.e. epoxy molding compound (EMC), is the most commonly used plastic in the molding method.

With reference to FIG. 5A, a transfer mold 30 in accordance with the prior art is operated. A chip 34 is placed in a lower mold 32. Then an upper mold 31 is covered on the lower mold 32 to form a mold cavity 33. A solid cylindrical plastic 35 is melted, and is pushed to fill in the mold cavity 33 by the plunger 36. As shown in FIG. 5B, the plastic 35 covers the chip 34 to form a semiconductor package. However, because the size of the mold cavity 33 is limited by the size of the upper mold 31 and the lower mold 32, so the size of the mold cavity 33 cannot be changed to make the semiconductor package lighter and thinner. Therefore, transfer molding method is gradually replaced by compression molding method because the trend is required the size of the semiconductor package requirements to be lighter and thinner.

With reference to FIG. 6A, a compression mold 40 in accordance with the prior art is operated. A chip 44 is disposed at an upper mold 41. A release film 43 is disposed on a lower mold 42. A plastic particle layer 45 is sprayed on the release film 43 in advance by a powder spraying device (not shown in FIG. 6A). The lower mold 42 pushes the release film 43 to reach a depth then the plastic particle layer 45 is melted. As shown in FIG. 6B, the lower mold 42 is pushed to the upper mold 41, so that the plastic particle layer 45 covers the chip 44 to form a semiconductor package. Thus, the compression molding method may adjust the size of the semiconductor package by controlling the thickness of the plastic particle layer 45 and the pushing depth of the release film 43 to meet different requirements of the size of the semiconductor package.

However, the prior art only uses single type of plastic in single molding method, and cannot meet specific molding method requirements. For example, high-fluidity plastic is used to solve the issue of wire sweep, but an overflow is occurred when a lower mold pushes a release film.

To overcome the shortcomings, the present invention provides a powder spraying device for semiconductor molding process and spraying method thereof to mitigate or to obviate the aforementioned problems.

### SUMMARY OF THE INVENTION

An objective of the present invention is to provide a powder spraying device for a semiconductor molding process and a spraying method thereof to meet specific molding method requirements.

To achieve the objective as mentioned above, the powder spraying device comprising:

a first powder spraying tube having a first opening formed on a bottom of the first powder spraying tube adjacent to one end of the first powder spraying tube;

a first gate mounted moveably on the first opening to selectively cover the first opening;

a second powder spraying tube arranged parallelly with the first powder spraying tube and having a second opening formed on a bottom of the second powder spraying tube adjacent to one end of the second powder spraying tube; and

a second gate mounted moveably on the second opening to selectively cover the second opening.

From the above description, the present invention primarily provides the powder spraying device having the first powder spraying tube and the second powder spraying tube arranged parallelly and filled with different plastic particles. By controlling the first opening and the second opening to be opened and closed at different times to spray different plastic particles so that the specific molding method requirements are met.

To achieve the objective as mentioned above, the spraying method comprising steps of:

(a) providing a release film and filling the first powder spraying tube and the second powder spraying tube with plastic particles, wherein the release film has a surface, and has a first spraying path and a second spraying path defined on the surface, a starting point of the first spraying path corresponds to the location of the first opening, a starting point of the second spraying path corresponds to the location of the second opening;

(b) moving the powder spraying device to align the first opening with the starting point of the first spraying path, and controlling the first gate to open the first opening, and controlling the second gate to close the second opening;

(c) moving the powder spraying device to move the first opening along with the first spraying path, and shaking the powder spraying device when the first opening is moved;

(d) controlling the first gate to close the first opening when the first opening aligns with an end point of the first spraying path;

(e) moving the powder spraying device to align the second opening with the starting point of the second spraying path, and controlling the second gate to open the second opening;

(f) moving the powder spraying device to move the second opening along with the second spraying path, and shaking the powder spraying device when the second opening is moved; and

(g) controlling the second gate to close the second opening when the second opening aligns with an end point of the second spraying path.

From the above description, the present invention primarily improves a powder spraying device for a semiconductor molding process in accordance with the prior art to the first powder spraying tube and the second powder spraying tube arranged parallelly and filled with different plastic particles. The first gate is controlled to selectively cover the first opening. The second gate is controlled to selectively cover the second opening. By controlling the first opening and the second opening to be opened and closed at different times to spray different plastic particles so that the specific molding method requirements are met.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a powder spraying device in accordance with the present invention;

FIG. 2 is a perspective view of a second embodiment of a powder spraying device in accordance with the present invention;

FIGS. 3A and 3B are spraying powder schematic views of a powder spraying device in accordance with the present invention according to a first spraying path;

FIGS. 3C and 3D are spraying powder schematic views of a powder spraying device in accordance with the present invention according to a second spraying path;

FIGS. 4A and 4B are spraying path schematic views of a powder spraying device in accordance with the present invention;

FIGS. 5A and 5B are process schematic views of a transfer molding method in accordance with the prior art; and

FIGS. 6A and 6B are process schematic views of a compression molding method in accordance with the prior art.

### DETAILED DESCRIPTION OF THE EMBODIMENTS

The present invention provides a powder spraying device for semiconductor molding process and spraying method thereof to meet specific molding method requirements. With embodiments and drawings thereof, the features of the present invention are described in detail as fallow.

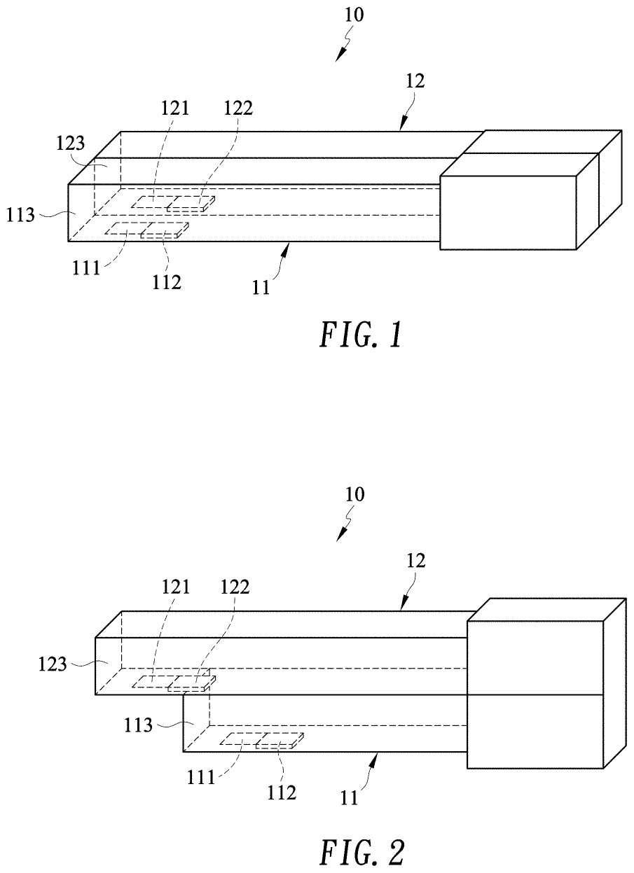

With reference to FIG. 1, a first embodiment of a powder spraying device 10 in accordance with the present invention comprises a first powder spraying tube 11 and a second powder spraying tube 12. The first powder spraying tube 11 and the second powder spraying tube 12 are arranged parallelly and are filled with plastic particles.

The first powder spraying tube 11 has a first opening 111, a first gate 112 and an end 113. The first opening 111 is formed on a bottom of the end 113. The first gate 112 is mounted moveably on the first opening 111 to selectively cover the first opening 111. In one embodiment, the first gate 112 is an electric control gate.

The second powder spraying tube 12 has a second opening 121, a second gate 122 and an end 123. The second opening 121 is formed on a bottom of the end 123. The second gate 122 is mounted moveably on the second opening 121 to selectively cover the second opening 121. In one embodiment, the second gate 122 is an electric control gate.

In the first embodiment of the present invention, the first powder spraying tube 11 and the second powder spraying tube 12 are arranged left and right parallelly, and are filled with different plastic particles. In one embodiment, the plastic particles have different fluidities after being melted. The first powder spraying tube 11 is formed integrally with the second powder spraying tube 12, but is not limited thereto.

Based on the above description of the first embodiment of the present invention, the powder spraying device 10 has the first powder spraying tube 11 and the second powder spraying tube 12 are arranged left and right parallelly, and are filled with different plastic particles. By controlling the first opening 111 and the second opening 121 to be opened or closed at different times, the powder spraying device 10 sprays different plastic particles to meet specific molding method requirements.

With reference to FIG. 2, a second embodiment of a powder spraying device 10a in accordance with the present invention also comprises the first powder spraying tube 11 and the second powder spraying tube 12 with different plastic particles filled in, but the first powder spraying tube 11 and the second powder spraying tube 12 are arranged up and down parallelly. The first powder spraying tube 11 is disposed under the second powder spraying tube 12. The length of the second powder spraying tube 12 is longer than the length of the first powder spraying tube 11 to expose the second opening 121.

In one embodiment, the plastic particles have different fluidities after being melted. The first powder spraying tube 11 is formed integrally with the second powder spraying tube 12, but is not limited thereto.

Based on the above description of the second embodiment of the present invention, although the first powder spraying tube 11 and the second powder spraying tube 12 are arranged up and down parallelly, the different length exposed the first opening 111 and the second opening 121. The powder spraying device 10a sprays different plastic particles to meet specific molding method requirements by controlling the first opening 111 and the second opening 121 to be opened or closed at different times.

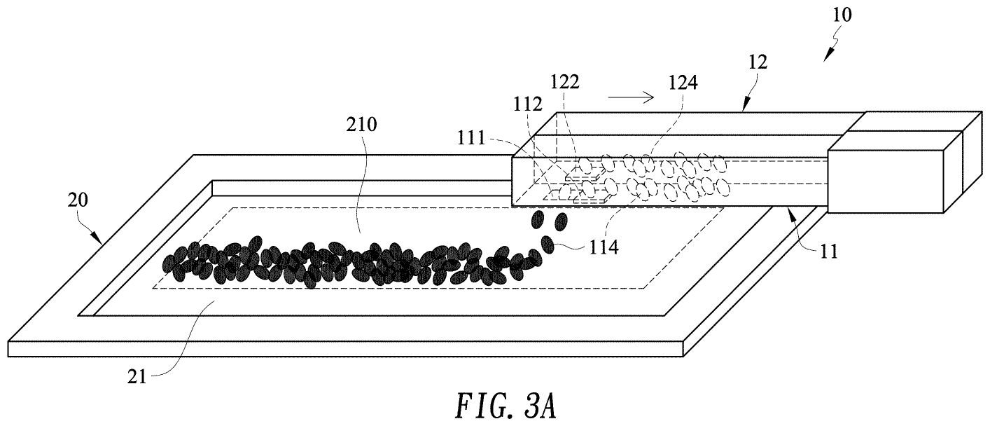

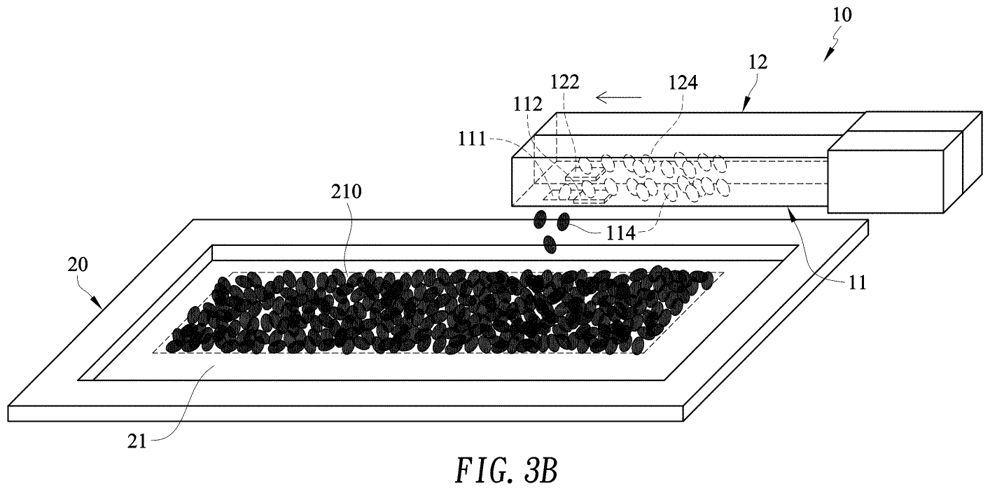

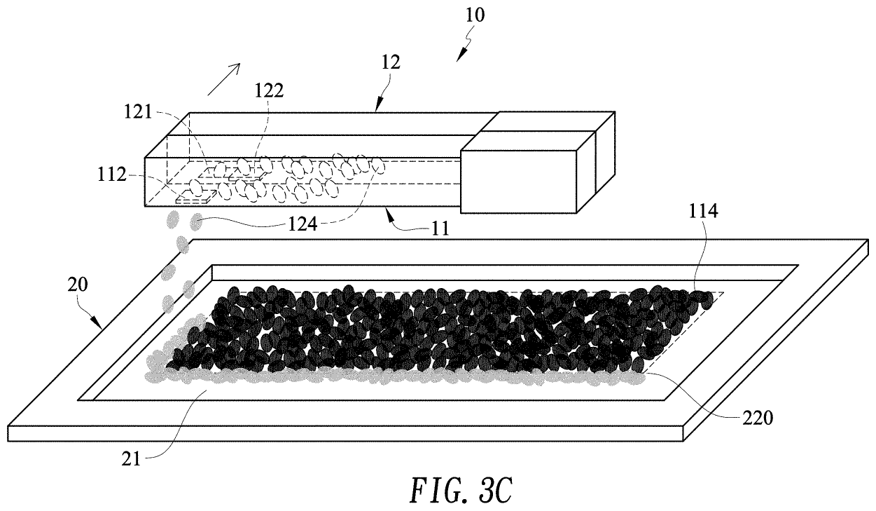

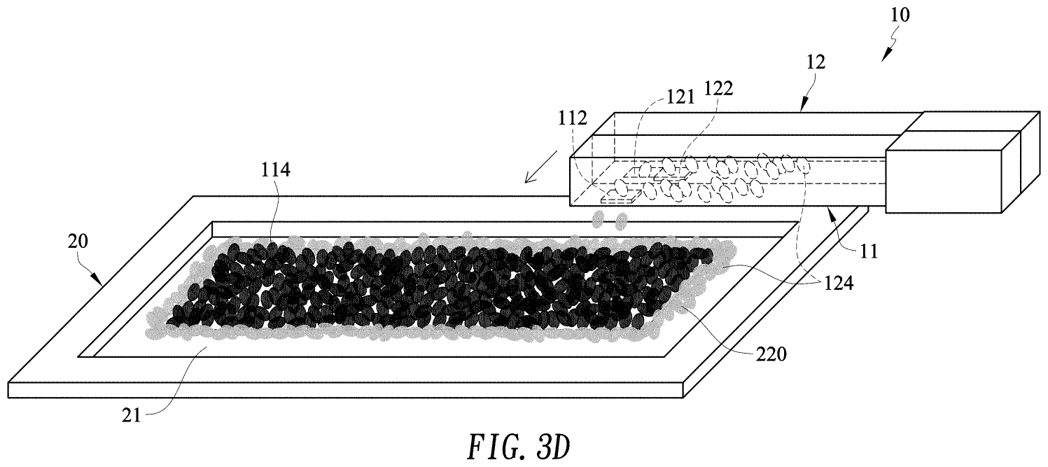

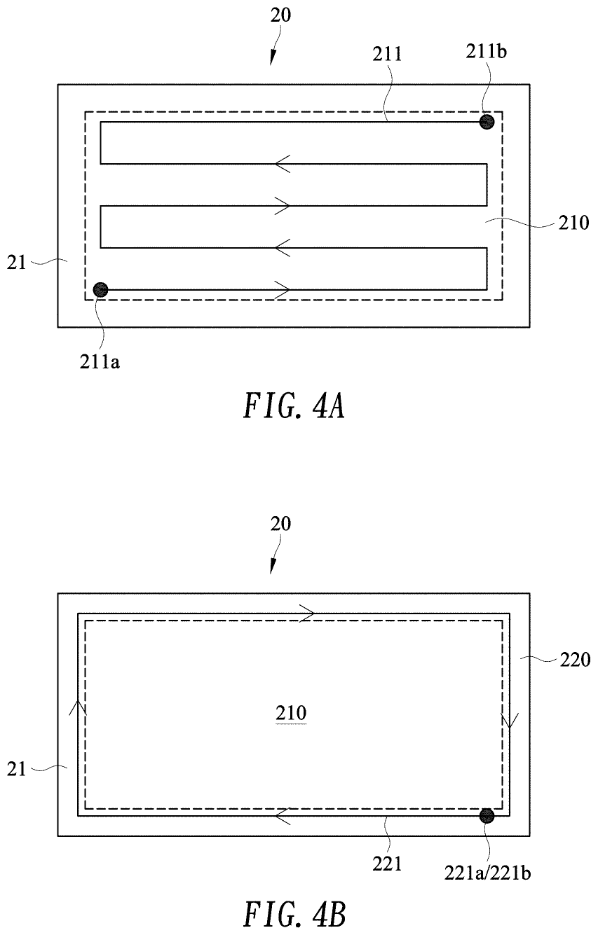

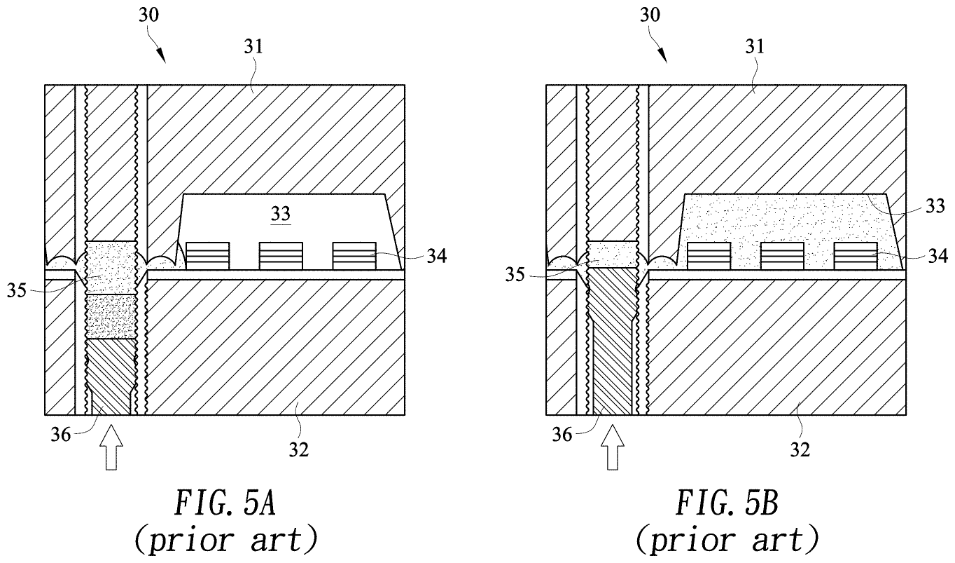

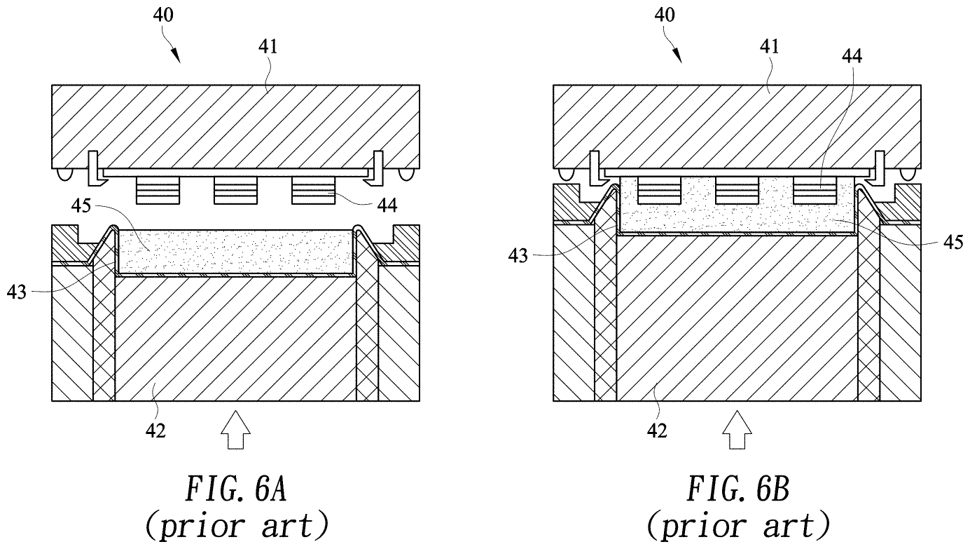

With reference from FIGS. 3A to 4B, a spraying method of the powder spraying device 10 comprises following steps (a) to (g).

With reference to FIGS. 1, 3A and 4A, in the step (a), a release film 20 is provided. The release film 20 has a surface 21. The surface 21 of the release film 20 has a first spraying area 210 and a second spraying area 220. In one embodiment, the first spraying area 210 does not overlap the second spraying area 220. A first spraying path 211 is defined to correspond to the first spraying area 210, and has a starting point 211a and an end point 211b. A second spraying path 221 is defined to correspond to the second spraying area 220, and has a starting point 221a and an end point 221b. In this embodiment, the shape of the second spraying path 221 is annular, so that the starting point 221a and the end point 221b are the same point. The starting point 211a of the first spraying path 211 corresponds to the location of the first opening 111. The starting point 221a of the second spraying path 221 corresponds to the location of the second opening 121. The first powder spraying tube 11 is filled with a first plastic particles 114, and the second powder spraying tube 12 is filled with a second plastic particles 124. In this embodiment, the fluidity of the first plastic particle 114 is higher than the fluidity of the second plastic particle 124 when the first and second plastic particles 114,124 are melted, but is not limited thereto.

With reference to FIGS. 1, 3A and 4A, in the step (b), the powder spraying device 10 is moved to align the first opening 111 with the starting point 211a of the first spraying path 211. The first gate 112 is controlled to open the first opening 111. The second gate 122 is controlled to close the second opening 121. In this embodiment, the first opening 111 is moved to correspond to the first spraying area 210 to align with the starting point 211a of the first spraying path 211.

With reference to FIGS. 3A and 4A, in the step (c), the first opening 111 of the powder spraying device 10 is moved from the starting point 211a to the end point 211b along with the first spraying path 211. The powder spraying device 10 is shaken to spray the first plastic particles 114 from the first opening 111 when the powder spraying device 10 moves. In one embodiment, the moving speed of the powder spraying device 10 determines the quantity of the first plastic particles 114 sprayed on the surface 21 of the release film 20. In this embodiment, the first plastic particles 114 are sprayed evenly on the surface 21 of the release film 20 along with the first spraying path 211 as shown in FIG. 4A by the first spraying tube 11.

With reference to FIGS. 3B and 4A, in the step (d), the first gate 112 is controlled to close the first opening 111 (not shown) when the first opening 111 aligns with the end point 211b of the first spraying path 211.

With reference to FIGS. 3C and 4B, in the step (e), the powder spraying device 10 is moved to align the second opening 121 with the starting point 221a of the second spraying path 221. The second gate 122 is controlled to open the second opening 121. In this embodiment, the second opening 121 is moved to correspond to the second spraying area 220 to align with the starting point 221a of the second spraying path 221.

With reference to FIGS. 3C and 4B, in the step (f), the second opening 121 of the powder spraying device 10 is moved from the starting point 221a to the end point 221b along with the second spraying path 221. The powder spraying device 10 is shaken to spray the second plastic particles 124 from the second opening 121 when the powder spraying device 10 moves. In one embodiment, the moving speed of the powder spraying device 10 determines the quantity of the second plastic particles 124 sprayed on the surface 21 of the release film 20. In this embodiment, the second plastic particles 124 are sprayed evenly on the surface 21 of the release film 20 along with the second spraying path 221 as shown in FIG. 4B by the second spraying tube 12.

With reference to FIGS. 3D and 4B, in the step (g), the second gate 121 is controlled to close the second opening 121 (not shown) when the second opening 121 aligns with the end point 221b of the second spraying path 221.

Hereby, the second plastic particles 124 surrounds the first plastic particles 114 on the surface 21 of the release film 20. The second plastic particles 124 has lower fluidity than the first plastic particles 114 when the first and second plastic particles 114, 124 are melted. When the release film 20 is provided to a single compression molding method, a lower mold with the release film 20 is heated then pushed to an upper mold. The first plastic particles 114 with the higher fluidity in the middle of the release film 20 cover a chip does not damage wires of the chip to avoid the issue of wire sweep. The second plastic particles 124 with the lower fluidity in the periphery of the release film 20 cover the chip to avoid that the melted second plastic particles 124 overflow from a substrate. Therefore, the present invention is meets specific molding method requirements in single molding method.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A powder spraying device for a semiconductor molding process comprising:
a first powder spraying tube having a first opening formed on a bottom of the first powder spraying tube adjacent to one end of the first powder spraying tube;
a first gate mounted moveably on the first opening to selectively cover the first opening;
a second powder spraying tube arranged parallelly with the first powder spraying tube and having a second opening formed on a bottom of the second powder spraying tube adjacent to one end of the second powder spraying tube; and
a second gate mounted moveably on the second opening to selectively cover the second opening.

2. The powder spraying device as claimed in claim 1, wherein the first powder spraying tube and the second powder spraying tube are arranged left and right parallelly.

3. The powder spraying device as claimed in claim 1, wherein
the first powder spraying tube and the second powder spraying tube are arranged up and down parallelly, the first powder spraying tube is disposed under the second powder spraying tube; and
the second powder spraying tube is longer than the first powder spraying tube to expose the second opening of the second powder spraying tube.

4. The powder spraying device as claimed in claim 1, wherein the first powder spraying tube and the second powder spraying tube are filled with different plastic particles.

5. The powder spraying device as claimed in claim 2, wherein the first powder spraying tube and the second powder spraying tube are filled with different plastic particles.

6. The powder spraying device as claimed in claim 3, wherein the first powder spraying tube and the second powder spraying tube are filled with different plastic particles.

7. The powder spraying device as claimed in claim 1, wherein the first gate and the second gate are electric control gates.

8. The powder spraying device as claimed in claim 2, wherein the first gate and the second gate are electric control gates.

9. The powder spraying device as claimed in claim 3, wherein the first gate and the second gate are electric control gates.

10. The powder spraying device as claimed in claim 1, wherein the first powder spraying tube is formed integrally with the second powder spraying tube.

11. The powder spraying device as claimed in claim 2, wherein the first powder spraying tube is formed integrally with the second powder spraying tube.

12. The powder spraying device as claimed in claim 3, wherein the first powder spraying tube is formed integrally with the second powder spraying tube.

13. A spraying method of a powder spraying device as claimed in claim 1, comprising steps of:
(a) providing a release film and filling the first powder spraying tube and the second powder spraying tube with plastic particles, wherein the release film has a surface, and has a first spraying path and a second spraying path defined on the surface, a starting point of the first spraying path corresponds to the location of the first opening, a starting point of the second spraying path corresponds to the location of the second opening;
(b) moving the powder spraying device to align the first opening with the starting point of the first spraying path, and controlling the first gate to open the first opening, and controlling the second gate to close the second opening;
(c) moving the powder spraying device to move the first opening along with the first spraying path, and shaking the powder spraying device when the first opening is moved;
(d) controlling the first gate to close the first opening when the first opening aligns with an end point of the first spraying path;
(e) moving the powder spraying device to align the second opening with the starting point of the second spraying path, and controlling the second gate to open the second opening;
(f) moving the powder spraying device to move the second opening along with the second spraying path, and shaking the powder spraying device when the second opening is moved; and
(g) controlling the second gate to close the second opening when the second opening aligns with an end point of the second spraying path.

14. The spraying method as claimed in claim 13, wherein in the step (a), the first spraying path does not overlap the second spraying path.

15. The spraying method as claimed in claim 13, wherein in the step (a), the first powder spraying tube and the second powder spraying tube are filled with different plastic particles.

16. The spraying method as claimed in claim 13, wherein in the step (c) or in the step (f) further comprises a step of determining a moving speed of the powder spraying device to define a quantity of the plastic particles sprayed on the release film.
